(19) United States
(12) Patent Application Publication
(10) Pub. No.: US 2013/0153005 A1
(43) Pub. Date: Jun. 20, 2013

(54) REINFORCEMENT ELEMENT FOR THIN FILM PHOTOVOLTAIC DEVICES AND THEIR METHODS OF MANUFACTURE

(71) Applicants: David W. Vernooy, Niskayuna, NY (US); Jeffrey Todd Knapp, Golden, CO (US)

(72) Inventors: David W. Vernooy, Niskayuna, NY (US); Jeffrey Todd Knapp, Golden, CO (US)

(73) Assignee: PRIMESTAR SOLAR, INC., Arvada, CO (US)

(21) Appl. No.: 13/326,973

(22) Filed: Dec. 15, 2011

(51) Int. Cl. H01L 31/048; H01L 31/18

(52) U.S. Cl. 136/251; 438/66; 257/E31.117

(57) ABSTRACT

Photovoltaic devices are provided that can include a transparent substrate defining a front surface; a plurality of thin film layers on an inner surface of the transparent substrate that is opposite of the front surface; a first lead connected to one of the photovoltaic cells defined by the plurality of thin film layers; an encapsulation substrate defining a connection aperture through which the first lead extends upon lamination of the encapsulation substrate and the transparent substrate together; and, a reinforcement element positioned on the front surface of the transparent substrate opposite from the connection aperture defined in the encapsulation substrate. Methods and kits are also provided for strengthening a photovoltaic device.

### FIELD OF THE INVENTION

The subject matter disclosed herein relates generally to photovoltaic devices including reinforcement element positioned on the transparent substrate to provide mechanical support opposite to the connection aperture defined in the encapsulation substrate.

### BACKGROUND OF THE INVENTION

Thin film photovoltaic (PV) modules (also referred to as “solar panels”), such as those based on cadmium telluride (CdTe) paired with cadmium sulfide (CdS) as the photo-reactive components, are gaining wide acceptance and interest in the industry. CdTe is a semiconductor material having characteristics particularly suited for conversion of solar energy to electricity. The junction of the n-type layer (e.g., CdS) and the p-type layer (e.g., CdTe) is generally responsible for the generation of electric potential and electric current when the CdTe PV module is exposed to light energy, such as sunlight. A transparent conductive oxide (“TCO”) layer is commonly used between the window glass and the junction forming layers to serve as the front electrical contact on one side of the device. Conversely, a back contact layer is provided on the opposite side of the junction forming layers and is used as the opposite contact of the cell.

An encapsulation substrate is positioned on the opposite side of the device from the window glass to encase the thin film layers. The encapsulation substrate also serves to mechanically support the window glass of the PV device. However, the encapsulation substrate typically contains a hole that enables connection of the photovoltaic device to lead wires for the collection of the DC electricity created by the PV device. The presence of the hole in the encapsulation substrate can induce a weak point in the device. For example, the PV device may be particularly susceptible to hail or other impact damage (e.g., in the form of chipping and/or cracking) in the window glass in the area at or near the encapsulation hole. This weakness can be exaggerated when the window glass is made from a specialty glass and/or a relatively thin glass.

As such, a need exists to inhibit and/or prevent cracking in the window glass of a PV device, particularly in the area where a hole is located in the encapsulation substrate.

### BRIEF DESCRIPTION OF THE INVENTION

Aspects and advantages of the invention will be set forth in part in the following description, or may be obvious from the description, or may be learned through practice of the invention.

Photovoltaic devices are generally provided in one embodiment. The photovoltaic device can include, for example, a transparent substrate defining a front surface; a plurality of thin film layers on an inner surface of the transparent substrate that is opposite of the front surface; a first lead connected to one part of the circuit formed by the photovoltaic cells defined by the plurality of thin film layers; an encapsulation substrate defining a connection aperture through which the first lead extends upon lamination of the encapsulation substrate and the transparent substrate together; and, a reinforcement element positioned on the front surface of the transparent substrate opposite from the connection aperture defined in the encapsulation substrate.

Methods of strengthening a photovoltaic device are also provided. For example, a reinforcement element can be applied onto the front surface of the transparent substrate and positioned opposite from the connection aperture defined in the encapsulation substrate to support the transparent substrate in an area opposite to the connection aperture defined by the encapsulation substrate. This step can be performed during the manufacture of the photovoltaic device, or after deployment of the photovoltaic device into the field.

Kits are also generally provided for use with a transparent substrate defining a plurality of photovoltaic cells connected in series to each other on an inner surface and a first lead connected to one of the photovoltaic cells, where the transparent substrate defines a front surface opposite to the inner surface. The kit can include an encapsulation substrate defining a connection aperture configured to allow the first lead to pass therethrough upon lamination to the inner surface of the transparent substrate; and, a reinforcement element configured to be applied onto the front surface of a transparent substrate and positioned opposite from the connection aperture defined in the encapsulation substrate. The reinforcement element can be configured to support the transparent substrate in an area opposite to the connection aperture defined by the encapsulation substrate.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary thin film photovoltaic device according to one embodiment;

FIG. 2 shows a front view of one exemplary embodiment of the photovoltaic device shown in FIG. 1;

FIG. 3 shows a front view of another exemplary embodiment of the photovoltaic device shown in FIG. 1;

FIG. 4 shows a front view of yet another exemplary embodiment of the photovoltaic device shown in FIG. 1;

FIG. 5 shows a front view of still another exemplary embodiment of the photovoltaic device shown in FIG. 1;

FIG. 6 shows a front view of still another exemplary embodiment of the photovoltaic device shown in FIG. 1; and,

FIG. 7 shows a front view of still another exemplary embodiment of the photovoltaic device shown in FIG. 1.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise specifically noted. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Thin film photovoltaic devices are generally provided having a reinforcement element positioned on a front surface of a transparent substrate (e.g., window glass) opposite from a connection aperture defined in an encapsulation substrate (e.g., back glass) to mechanically support the transparent substrate in the area opposite from the connection aperture. As such, the thin film photovoltaic devices can help support the transparent substrate in a known area of weakness, especially from direct impact (e.g., from hail). Methods are also generally provided for making such thin film photovoltaic devices.

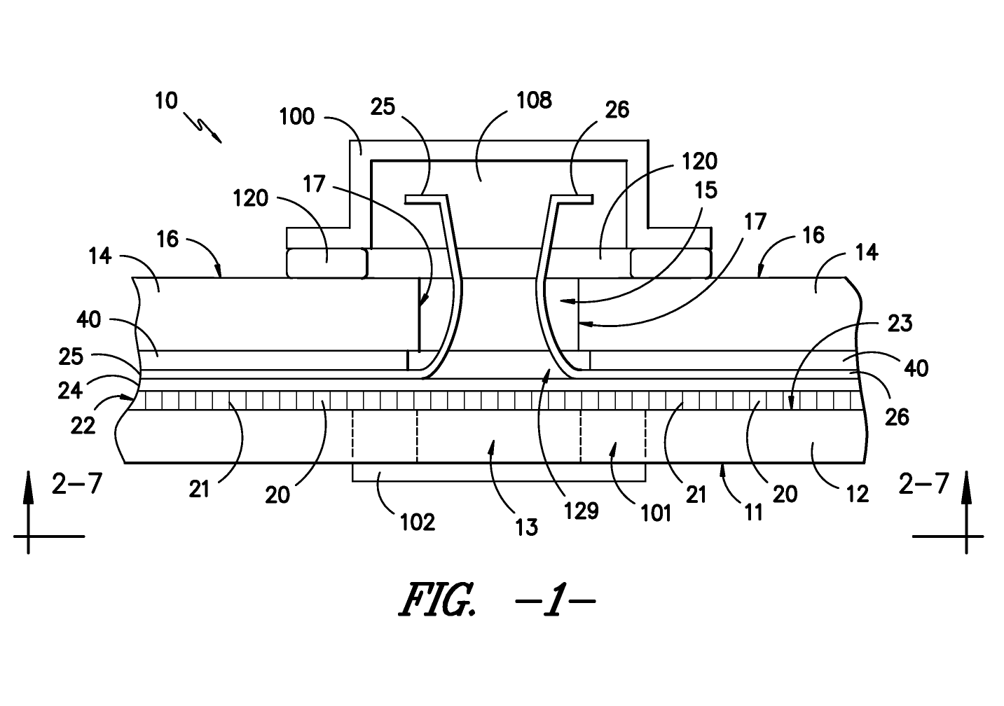

FIG. 1 shows a cross-sectional view of an exemplary thin film photovoltaic device 10 having a reinforcement element 102 on the front surface 11 of the transparent substrate 12. As shown, the reinforcement element 102 is positioned opposite from the connection aperture 15 defined in the encapsulation substrate 14 in order to mechanically support the transparent substrate 12 in the area 13 opposite to the connection aperture 15.

A support area 101 is generally defined on the front surface 11 of the transparent substrate 12 that is encompassed within the general size of the reinforcement element 102. In one embodiment, this support area 101 can be larger than the area 13 opposite to the connection aperture 15 in order to distribute any force applied to the area 13 across the transparent substrate 12. Such a design can be particularly helpful when a small object (not shown, e.g., having a size that is less than the size of the area 13) impacts the transparent substrate 12 in the area 13 (e.g., a hail strike onto the area 13). In one embodiment, the support area 101 on the front surface 11 of the transparent substrate 12 can be about 3% to about 25% larger than area 13 opposite to the connection aperture 15 (i.e., the size of the connection aperture 15 defined in the encapsulation substrate 14), such as about 5% to about 15% larger.

By employing a substantially transparent material (e.g., glass, Poly(methyl methacrylate) (PMMA), a polycarbonate lens material, etc.) for the reinforcement element 102 and/or by designing the reinforcement material to define open areas, the reinforcement element 102 can be, in one particular embodiment, configured to allow at least about 75% of the light energy (e.g., light within the visible wavelength region) to which the front surface 11 is exposed to pass through the reinforcement element 102, such as at least about 90% of the light energy. As such, the reinforcement element 102 can have a minimal effect on the light collection of the device 10.

The reinforcement element 102 can be constructed from any suitable material that provides sufficient stiffness to mechanically support the transparent substrate 12 in the area 13 opposite to the connection aperture 15. For example, in certain embodiments, the reinforcement element 102 can be constructed from a glass, a plastic material, a hard rubber material, a metal material (e.g., a metal wire), or a combination thereof. Selection of the material for construction of the reinforcement element 102 may be selected based, in part, on the particular configuration selected. It is to be noted that, the area of the device 10 adjacent the connection aperture 15 may be inactive in certain embodiments, which would allow for the possibility to employ a translucent or opaque reinforcing material (e.g., metal or hard rubber) for the reinforcement element 102 as its presence immediately above the connection aperture 15 would not have a negative effect on module efficiency in such a device 10. If such a translucent or opaque material is used, the amount of active area, however, of the device 10 blocked by the reinforcement element 102 should be kept to a minimum needed for sufficient strengthening.

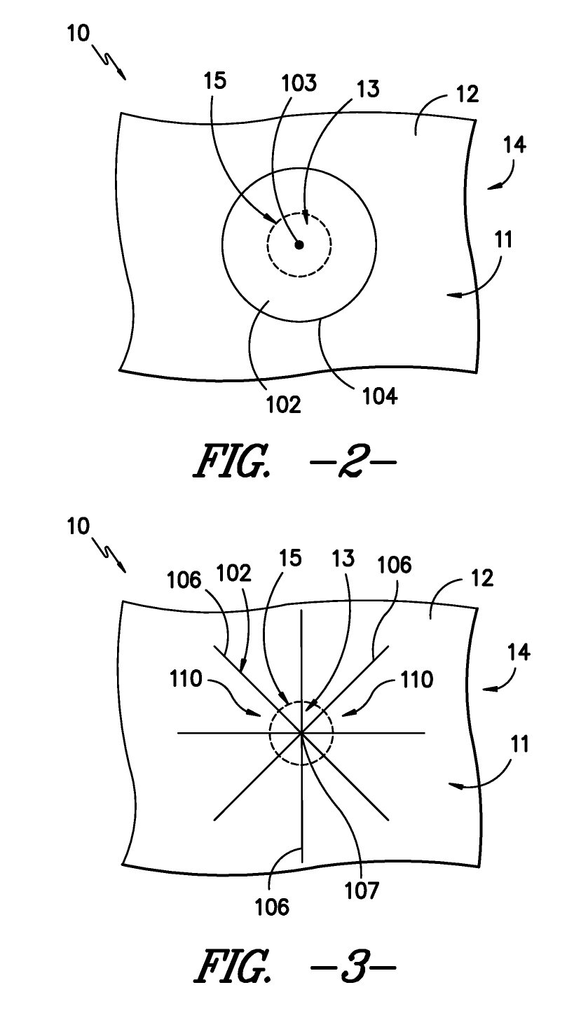

For example, FIG. 2 shows a top view (i.e., the view from which light travels into the device 10) of one embodiment of the device 10 of FIG. 1. In this embodiment, the reinforcement element 102 defines a plate 104 positioned over the area 13 opposite to the connection aperture 15 of the encapsulation substrate 14. As shown, the plate 104 defines a center point 103 on the front surface 11 of the transparent substrate 12 that is opposite the area 13 corresponding to the connection aperture 15 in the encapsulation substrate 14. For instance, in particular embodiments, the center point 103 on the front surface 11 of the transparent substrate 12 can be centered with respect to the area 13 opposite to the connection aperture 15 defined in the encapsulation substrate 14.

Although shown as having a substantially circular disk shape in the embodiment of FIG. 2, the reinforcement element 102 can define other shapes. FIG. 8 shows, for example, a reinforcement element 102 defining a plate 104 that has a rectangular shape (e.g., a square shape) positioned over the area 13 opposite to the connection aperture 15 of the encapsulation substrate 14. Alternatively, FIG. 9 shows the a reinforcement element 102 defining a plate 104 that has a star-like shape positioned over the area 13 opposite to the connection aperture 15 of the encapsulation substrate 14. Other shapes, although not specifically shown, can be defined by the plate 104, such as polygons, ovals, etc. As such, the specific geometry of the plate 104 can vary as desired, as long as the plate 104 provides sufficient support to the area 13 opposites to the connection aperture 15.

In such embodiments, the reinforcing element 102 can be, in particular embodiments, a glass disk (e.g., borosilicate glass, soda-lime glass, etc.) or another suitable transparent material (e.g., a plastic film) that is adhered to the front surface 11 of the transparent substrate 12 with a transparent adhesive (e.g., EVA).

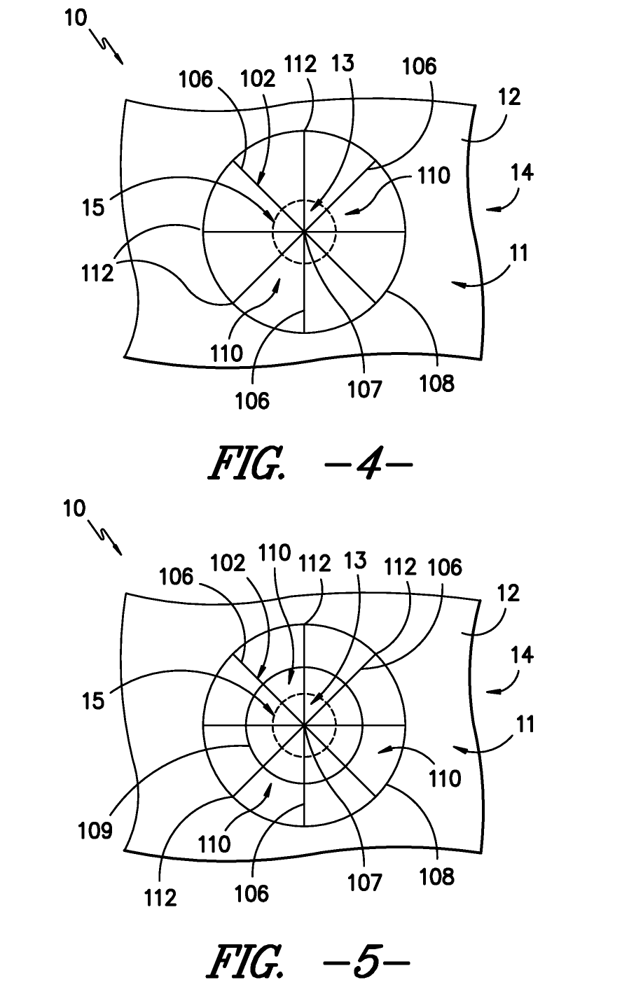

In alternative embodiments, the reinforcement element 102 can be designed from a plurality of spokes 106 (e.g., as shown in FIGS. 3-7) instead of a plate-like element as shown in FIGS. 2 and 8-9.

FIG. 3 shows a top view (i.e., the view from which light travels into the device 10) of another embodiment of the device 10 of FIG. 1. In this embodiment, the reinforcement element 102 is formed from a plurality of intersecting reinforcement spokes 106. The intersecting reinforcement spokes 106 are arranged to define exposed areas 110 on the front surface 11 of the transparent substrate 12 therebetween to allow light energy pass therethrough. In the embodiment shown, each of the intersecting reinforcement spokes 106 extend radially from a common intersection 107 on the front surface 11 of the transparent substrate 12. For example, the common intersection 107 on the front surface 11 of the transparent substrate 12 can be within the area 13 opposite to the connection aperture 15 in the encapsulation substrate 14. In one embodiment, the common intersection 107 can be centered with respect to the area 13 opposite to the connection aperture 15 in the encapsulation substrate 14.

Although shown having three intersecting reinforcement spokes 106, any suitable number of intersecting reinforcement spokes 106 can be used to form the reinforcement element 102. Similarly, any suitable pattern or design can be formed with the intersecting reinforcement spokes 106 on the front surface 11 of the transparent substrate 12. Given that the reinforcement spokes 106 are intentionally narrow (e.g., about 3 mm wide or less; such as about 0.1 mm wide to about 1.5 mm wide), the reinforcement spokes 106 need not necessarily be made of a transparent material, given the minimal amount of sunlight potentially blocked thereby. As such, the reinforcement spokes 106 could, for example, be made of a metal wire, a para-aramid synthetic fiber (e.g., such as the one sold under the trade name “Kevlar”), carbon fiber, etc., or another wire or fibrous material that would provide sufficient strength and/or toughness, as needed to resist impact to the area.

FIG. 4 shows an embodiment having a similar pattern to that of FIG. 2 where the intersecting reinforcement spokes 106 collectively form the reinforcement element 102. In this embodiment, each intersecting reinforcement spokes 106 terminates at a connection point 112 attached to a perimetrical border bar 108. The perimetrical border bar 108 generally defines the outer perimeter of the reinforcement element 102. The perimetrical border bar 108, especially if wider than 3 mm, would likely be most favorably made of a transparent material to facilitate transmittance of light to the device 10 beneath. If narrower than 1.5 mm, the strength thereof could be more of a focus.

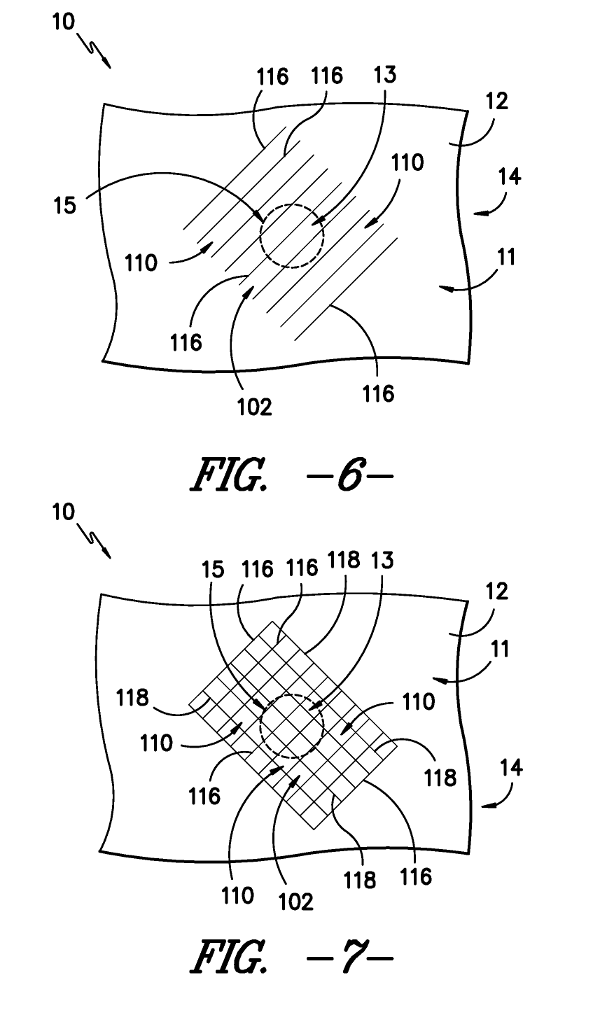

FIG. 5 shows an embodiment having a similar pattern to that of FIG. 4 where the intersecting reinforcement spokes 106 form the reinforcement element 102 and terminate at the connection point 112 attached to a perimetrical border bar 108. In this embodiment, an inner radial bar 109 is connected to each intersecting reinforcement spoke 106 in addition to the perimetrical border bar 108. It is noted that although shown with a single inner radial bar 109, any suitable number of inner radial bars 109 can be included in the reinforcement element 102. The material choice for each inner radial bars 109 may be similar to that used for the perimetrical border bar 108.

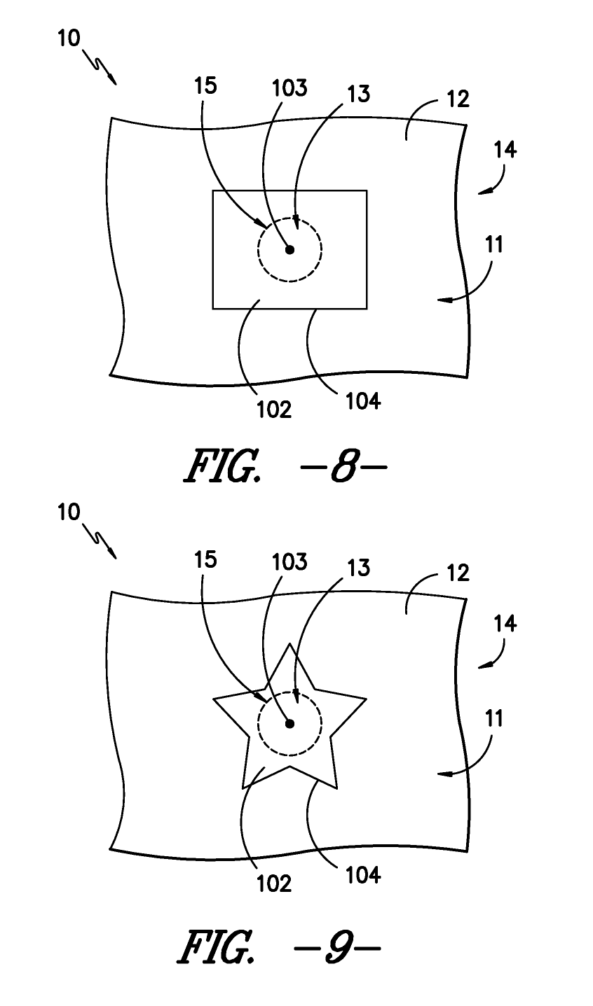

FIG. 6 shows a top view (i.e., the view from which light travels into the device 10) of another embodiment of the device 10 of FIG. 1. In this embodiment, the reinforcement element 102 is formed from a plurality of reinforcement bars 116 that do not intersect with each other. For example, the reinforcement bars 116 can be oriented substantially parallel to each other. As such, the reinforcement bars 116 are arranged to define exposed areas 110 on the front surface 11 of the transparent substrate 12 therebetween to allow light energy pass therethrough.

FIG. 7 shows a top view (i.e., the view from which light travels into the device 10) of yet another embodiment of the device 10 of FIG. 1. In this embodiment, the reinforcement element 102 is formed from a plurality of first reinforcement bars 116 oriented in a first direction and a plurality of second reinforcement bars 118 oriented in a second direction. The first direction and the second direction generally intersect each other such that the first reinforcement bars 116 intersect at least one of the second reinforcement bars 118. In the embodiment shown, for example, the first reinforcement bars 116 can be oriented substantially parallel to each other, and the second reinforcement bars 118 can be oriented substantially parallel to each other, with the first direction being substantially perpendicular to the second direction. As such, the first reinforcement bars 116 and second reinforcement bars 118 are arranged to define exposed areas 110 on the front surface 11 of the transparent substrate 12 therebetween to allow light energy pass therethrough.

In the embodiments shown in FIGS. 3-7, the intersecting reinforcement spokes 106, the perimetrical border bar 108, inner radial bar 109, and/or the reinforcement bars 116, 118 can be, in particular embodiments, constructed from a metal, a plastic material, a hard rubber material, etc. For example, the intersecting reinforcement spokes 106, the perimetrical border bar 108, inner radial bar 109, and/or the reinforcement bars 116, 118 can be made from wire-like rods in order to minimize the surface area on the front surface 11 of the transparent substrate 12 that is shaded by the reinforcement element 102. Such a material can be adhered to the front surface 11 or otherwise pressed into the transparent substrate 12 (e.g., formed integrally within the transparent substrate 12).

As stated, the connection aperture 15 allows a first lead 25 and an optional second lead 26 to extend through the encapsulation substrate 14. The first lead 25 and an optional second lead 26 are generally configured to collect the DC current generated by the plurality of photovoltaic cells 20 in the device 10. A junction box 100 can be positioned (e.g., adhered) on the back surface 16 of the encapsulation substrate 14 over the connection aperture 15 and can be connected to the first lead 25 and an optional second lead 26. The connection aperture 15 can generally have a perimeter defined by an aperture wall 17 of the encapsulation substrate 14.

In one embodiment, the junction box 100 can be directly attached to the back surface 16 of the encapsulation substrate 14. Alternatively, the junction box 100 can be indirectly attached to the back surface 16, such as through a washer member 120 as shown in FIG. 1. The washer member 120 can be positioned on the back surface 16 of the encapsulation substrate 14 between the junction box 100 and the encapsulation substrate 14. For example, the washer member 120 can, in one embodiment, be perimetrically positioned about a perimeter of the connection aperture 15. As such, the junction box 100 can be attached to the washer member 120 such that the junction box 100 is indirectly attached to the encapsulation substrate 14 through the washer member 120.

Referring again to FIG. 1, the transparent substrate 12 can be, in one embodiment, a “superstrate,” as it can be the substrate on which the subsequent layers are formed even though it faces upward to the radiation source (e.g., the sun) when the photovoltaic device 10 is in use. The transparent substrate 12 can be a high-transmission glass (e.g., high transmission borosilicate glass), low-iron float glass, or other highly transparent glass material. The glass is generally thick enough (e.g., from about 0.5 mm to about 10 mm thick) to provide support for the subsequent film layers, and is substantially flat to provide a good surface for forming the subsequent film layers. In one embodiment, the glass 12 can be a low iron float glass containing less than about 0.015% by weight iron (Fe), and may have a transmissiveness of about 0.9 or greater in the spectrum of interest (e.g., wavelengths from about 300 nm to about 900 nm). In another embodiment, a high strain-point glass, such as borosilicate glass, may be utilized so as to better withstand high temperature processing. For example, the transparent substrate 12 can be a relatively thin sheet of borosilicate glass, such as having a thickness of about 0.5 mm to about 2.5 mm.

The encapsulation substrate 14 defines a connection aperture 15 providing access to the underlying components to collect the DC electricity generated by the photovoltaic device 10. In one particular embodiment, the encapsulation substrate 14 is a glass substrate, such as those discussed above with respect to the transparent substrate 12. For example, in one embodiment, the transparent substrate 12 can be a borosilicate glass having a thickness of about 0.5 mm to about 2.5 mm, while the encapsulation substrate 14 is a low iron float glass having a thickness that is greater than that of the transparent substrate 12 (e.g., about 3 mm to about 10 mm).

The thin film stack 22 in the device 10 can include a plurality of thin film layers positioned on the transparent substrate 12. The thin film stack can define individual photovoltaic cells 20 separated by scribe lines 21. The individual photovoltaic cells 20 are electrically connected together in series. In one particular embodiment, the thin film stack 22 can include a transparent conductive oxide layer (e.g., cadmium stannate or stoichiometric variation of cadmium, tin, and oxygen; indium tin oxide, etc.) on the transparent substrate 12, an optional resistive transparent buffer layer (e.g., a combination of zinc oxide and tin oxide, etc.) on the transparent conductive oxide layer, an n-type window layer on the resistive transparent buffer layer, an absorber layer on the n-type window layer, and a back contact on the absorber layer. In one particular embodiment, the n-type window layer can include cadmium sulfide (i.e., a cadmium sulfide thin film layer), and/or the absorber layer can include cadmium telluride (i.e., a cadmium telluride thin film layer). Other thin film layers may also be present in the film stack, as desired. Generally, the back contact defines the exposed surface of the thin film stack 22, and serves as an electrical contact of the thin film layers opposite the front contact defined by the transparent conductive oxide layer.

An insulating layer 24 is provided on the thin film stack 22 to isolate the back contact of the thin film stack 22 from the leads 25, 26. The insulating layer 24 generally includes an insulating material that can prevent electrical conductivity therethrough. Any suitable material can be used to produce the insulating layer 24. In one embodiment, the insulating layer 24 can be an insulating polymeric film coated on both surfaces with an adhesive coating. The adhesive coating can allow for adhesion of the insulating layer 24 to the underlying thin film stack 22 and for the adhesion of the leads 25, 26 to the insulating layer 24. For example, the insulating layer 24 can include a polymeric film of polyethylene terephthalate (PET) having an adhesive coating on either surface. The adhesive coating can be, for example, an acrylic adhesive, such as a pressure sensitive acrylic adhesive.

In one particular embodiment, the insulating layer 24 is a strip of insulating material generally oriented in a direction perpendicular to the orientation of the scribe lines 21. The insulating layer 24 can have a thickness in the z-direction suitable to prevent electrical conductivity from the underlying thin film stack 22, particularly the back contact, to any subsequently applied layers. In one particular embodiment, the insulating layer 24 can prevent electrically conductivity between the thin film stack 22 and the leads 25, 26.

Optionally, an intra-laminate disk layer (not shown) can be positioned on the insulating layer 24 over an area of the thin film stack 22 to be exposed by the connection aperture 15 of the encapsulation substrate 14. For example, the intra-laminate disk layer can extend over a protected area that equal to or larger than the connection aperture 15 defined by the encapsulation substrate 14.

When present, the intra-laminate disk layer can define a substantially circular disk in the x, y plane (which is perpendicular to the z-direction D_{z}). This shape can be particularly useful when the connection aperture 15 in the encapsulation substrate 14 has the same shape in the x, y plane (e.g., circular). As such, the intra-laminate disk layer can be substantially centered with respect to the connection aperture 15 defined by the encapsulation substrate 14. Also, with this configuration, the disk diameter of the intra-laminate disk layer can be larger than the aperture diameter defined by the connection aperture 15. For instance, the disk diameter can be at about 5% larger to about 200% larger than the connection diameter, such as about 10% larger to about 100% larger. However, other sizes and shapes may be used as desired. In certain embodiments, the intra-laminate disk layer can define a thickness, in the z-direction, of about 50 μm to about 400 μm. If too thick, however, the intra-laminate disk layer could lead to de-lamination of the device 10.

The intra-laminate disk layer can, in one embodiment, be a polymeric film. In one particular embodiment, the film can be a polymeric film, including polymers such as polyethylene, polypropylene, polyethylene terephthalate (PET), ethylene-vinyl acetate copolymer, or copolymers or mixtures thereof. Alternatively, the intra-laminate disk layer can be a sheet of thin glass, e.g., having a thickness of about 0.02 mm to about 0.25 mm (e.g., 0.04 mm to 0.15 mm). When constructed of glass, the intra-laminate disk layer can provide excellent barrier properties to moisture along with providing some structural support to the device 10. It is to be understood that the intra-laminate disk layer could yet instead be in the form of a laminated glass disk, with a glass sheet having a laminate layer thereon being made, for example, of a polymeric film as per above. Such a laminated glass disk could provide the adhesion characteristics of the polymeric film and the barrier properties of the glass, and may also play a role in making the hole region more resistant to hail impact, especially if it is comprised of glass.

In one embodiment, for example, the intra-laminate disk layer can be constructed of a film having a polymeric coating on one or both surfaces. The polymeric coating can include a hydrophobic polymer configured to inhibit moisture ingress through the intra-laminate disk layer and/or around the intra-laminate disk layer. In addition, the polymeric coating can help adhere the intra-laminate disk layer to the underlying layers (e.g., the thin film stack 22) and subsequently applied layers (e.g., the adhesive layer 40). In one particular embodiment, the polymeric coating can include a material similar to the adhesive layer 40 in the device (e.g., an ethylene-vinyl acetate copolymer).

A sealing layer (not shown) can also be applied on the thin film stack 22 and the insulating layer 24 (and optional intra-laminate disk layer, if present). When both the sealing layer and the intra-laminate disk layer are present, the sealing layer can help to hold the intra-laminate disk layer in place in the finished PV device 10 by providing the intra-laminate disk in a smaller size in the x, y plane (e.g., a smaller diameter) than the sealing layer, such that the sealing layer bonds the edges of the intra-laminate disk layer to the thin film stack 22.

Whether or not the intra-laminate disk layer, is present, the sealing layer can be positioned where the connection aperture 15 of the encapsulation substrate 14 is located on the device 10. The composition of the sealing layer (e.g., a synthetic polymeric material, as discussed below) can be selected such that the sealing layer has a moisture vapor transmission rate that is 0.5 g/m²/24 hr or less (e.g., 0.1 g/m²/24 hr or less, such as 0.1 g/m²/24 hr to about 0.001 g/m²/24 hr). As used herein, the “moisture vapor transmission rate” is determined according to the test method of ASTM F1249 at a 0.080″ thickness. As such, the sealing layer can form a moisture barrier between the connection aperture 15 in the encapsulation substrate 14 and the thin film stack 22 and define a protected area thereon.

In one embodiment, the sealing layer can be sized to be larger than the connection aperture 15 defined by the encapsulation substrate 14 (e.g., if circular, the sealing layer can have a diameter that is larger than the diameter of the connection aperture 15). In this embodiment, the sealing layer can not only form a moisture barrier between the protected area of the thin film stack 22 and the connection aperture 15, but also can help adhere the encapsulation substrate 14 to the underlying layers of the device 10.

In one particular embodiment, the sealing layer can include a synthetic polymeric material. The synthetic polymeric material can, in one embodiment, melt at the lamination temperature, reached when the encapsulation substrate 14 is laminated to the substrate 12, such that the synthetic polymeric material melts and/or otherwise conforms and adheres to form a protected area on the thin film stack 22 where the connection aperture 15 is located on the device 10. For instance, the synthetic polymeric material can melt at laminations temperatures of about 120° C. to about 160° C.

The synthetic polymeric material can be selected for its moisture barrier properties and its adhesion characteristics, especially between the encapsulation substrate 14 (e.g., a glass) and the back contact layer(s) of the thin film stack 22. For example, the synthetic polymeric material can include, but is not limited to, a butyl rubber or other rubber material. Though the exact chemistry of the butyl rubber can be tweaked as desired, most butyl rubbers are a copolymer of isobutylene with isoprene (e.g. produced by polymerization of about 98% of isobutylene with about 2% of isoprene). One particularly suitable synthetic polymeric material for use in the sealing layer is available commercially under the name HelioSeal® PVS 101 from ADCO Products, Inc. (Michigan Center, Mich.).

The leads 25, 26, in one embodiment, can be applied as a continuous strip over the insulating layer 24 and the optional sealing layer, and then the continuous strip can then be severed to produce the first lead 25 and the second lead 26, as shown in FIG. 1. The leads 25, 26 can be constructed from any suitable material. In one particular embodiment, the leads 25, 26 is a strip of metal foil. For example, the metal foil can include a conductive metal.

Sealing strips (not shown) can extend over a portion of the first lead 25 and the second lead 26, respectively. The sealing strips may be connected to each other, such as in the form of a ring. No matter their exact configuration, the sealing layer can be thermally bonded to the first sealing strip and the second sealing strip to surround the first lead 25 and second lead 26, respectively. Thus, the first sealing strip and the sealing layer can form a circumferential moisture barrier about the first lead 25 to inhibit moisture ingress along the first lead 25 and into the device 10. Likewise, the second sealing strip and the sealing layer can form a circumferential moisture barrier about the second lead 26 to inhibit moisture ingress along the second lead 26 and into the device 10.

The sealing strips can have any composition as discussed above with respect to the sealing layer. Although the composition of the sealing strips may be selected independently from the each other and/or the sealing layer, in one embodiment, the sealing strips can have the same composition as the sealing layer (e.g., a butyl rubber).

The encapsulation substrate 14 can be adhered to the photovoltaic device 10 via an adhesive layer 40 and, if present, the sealing layer and the sealing strips (or ring). The adhesive layer 40 can be generally positioned over the leads 25, 26, insulating layer 24, and any remaining exposed areas of the thin film stack 22. The adhesive layer 40 can generally define an adhesive gap that generally corresponds to the connection aperture 15 defined by the encapsulation substrate 14. As such, the first lead 25 and second lead 26 can extend through the adhesive gap. The adhesive layer 40 can generally protect the thin film stack 22 and attach the encapsulation substrate 14 to the underlying layers of the device 10. The adhesive layer can be constructed from, for example, ethylene vinyl acetate (EVA), polyvinyl butyral (PVB), silicone based adhesives, or other adhesives which are configured to prevent moisture from penetrating the device.

Finally, the junction box 100 can be attached to the device 10 and positioned to cover the connection aperture 15, such as shown in FIG. 1 and discussed above. The junction box 100 can be configured to electrically connect the photovoltaic device 10 by completing the DC circuit and provide a positive lead wire (not shown) and a negative lead wire (not shown) for further collection of the DC electricity produced by the photovoltaic device 10.

Other components and features (not shown) can be included in the exemplary device 10, such as bus bars, external wiring, laser etches, etc. For example, edge sealing layers can be applied around the edges of the device 10 to seal the substrate 12 to the encapsulation substrate 14 along each edge. Additionally, bus bars (not shown) can be attached to connect the photovoltaic cells 20 of the thin film stack 22 to the first lead 25 and second lead 26. Since the photovoltaic cells 20 are connected to each other in series, the bus bars can serve as opposite electrical connections (e.g., positive and negative) on the photovoltaic device 10.

Methods of manufacturing the devices 10 of FIGS. 1-7 are also encompassed by the present disclosure.

In one embodiment, for example, a method is generally provided for supporting a transparent substrate in an area opposite from a connection aperture defined in an encapsulating substrate of a photovoltaic device that has a first lead. The method can generally include: laminating an encapsulation substrate onto a transparent substrate such that a first lead extends through a connection aperture from a plurality of thin film layers on an inner surface of the transparent substrate that is opposite of a front surface, and applying a reinforcement element onto the front surface of the transparent substrate positioned opposite from the connection aperture defined in the encapsulation substrate to support the transparent substrate in an area opposite to the connection aperture defined by the encapsulation substrate.

It is to be understood that the reinforcement element could be placed as part of the initial process of making the device or attached later (e.g., after deployment of the PV device into service in the field). The attachment could be achieved, for example, through the provision of an adhesive backing on the reinforcement element and/or by applying the adhesive separately (e.g., to the surface of the PV device.

Kits are also disclosed that generally include a reinforcement element (e.g., any of the reinforcement elements 102 of FIGS. 1-7), an encapsulation substrate defining a connection aperture, and optionally other components of the devices 10 of FIGS. 1-7. For example, the kit for use with a photovoltaic device can include an encapsulation substrate defining a connection aperture having a perimeter defined by an aperture wall of the encapsulation substrate and a reinforcement element configured to be applied onto a front surface of a transparent substrate positioned opposite from the connection aperture defined in the encapsulation substrate to support the transparent substrate in an area opposite to the connection aperture defined by the encapsulation substrate.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A photovoltaic device, comprising:
a transparent substrate defining a front surface;
a plurality of thin film layers on an inner surface of the transparent substrate that is opposite of the front surface, wherein the plurality of thin film layers define a plurality of photovoltaic cells connected to each other in a circuit;
a first lead connected to one part of the circuit;
an encapsulation substrate defining a connection aperture through which the first lead extends upon lamination of the encapsulation substrate and the transparent substrate together; and,
a reinforcement element positioned on the front surface of the transparent substrate and located opposite from the connection aperture defined in the encapsulation substrate.

2. The photovoltaic device as in claim 1, wherein the reinforcement element covers the support area on the front surface of the transparent substrate that is about 3% to about 25% larger than the connection aperture defined in the encapsulation substrate.

3. The photovoltaic device as in claim 1, wherein the reinforcement element covers a support area on the front surface of the transparent substrate that is about 5% to about 15% larger than the connection aperture defined in the encapsulation substrate.

4. The photovoltaic device as in claim 1, wherein the reinforcement element is configured to allow at least about 75% of light energy to pass through the reinforcement element.

5. The photovoltaic device as in claim 1, wherein the reinforcement element is configured to allow at least about 90% of light energy to pass through the reinforcement element.

6. The photovoltaic device as in claim 1, wherein the reinforcement element comprises material that is at least about 50% transparent to visible light.

7. The photovoltaic device as in claim 1, wherein the reinforcing element defines a plate.

8. The photovoltaic device as in claim 7, wherein the reinforcing element comprises glass.

9. The photovoltaic device as in claim 7, wherein the plate defines a center point on the front surface of the transparent substrate that is centered with respect to the connection aperture in the encapsulation substrate.

10. The photovoltaic device as in claim 1, wherein the reinforcement element comprises a plurality of intersecting reinforcement spokes, the intersecting reinforcement spokes being arranged to define exposed areas on the front surface of the transparent substrate therebetween to allow light energy pass therethrough.

11. The photovoltaic device as in claim 10, wherein each of the intersecting reinforcement spokes extend radially from a common intersection on the front surface of the transparent substrate.

12. The photovoltaic device as in claim 11, wherein the common intersection on the front surface of the transparent substrate is opposite the connection aperture in the encapsulation substrate.

13. The photovoltaic device as in claim 11, wherein the common intersection on the front surface of the transparent substrate is centered with respect to the connection aperture in the encapsulation substrate.

14. The photovoltaic device as in claim 11, wherein each intersecting reinforcement spoke terminates at a connection to a perimetrical border bar.

15. The photovoltaic device as in claim 11, wherein the reinforcement element further comprises an inner radial bar connected to each intersecting reinforcement spoke.

16. The photovoltaic device as in claim 10, wherein the reinforcing element comprises a metal, a fiber, or a plastic material.

17. The photovoltaic device as in claim 1, wherein the reinforcement element comprises a plurality of reinforcement bars that are oriented substantially parallel to each other.

18. The photovoltaic device as in claim 1, wherein the reinforcement element comprises a plurality of first reinforcement bars oriented in a first direction and a plurality of second reinforcement bars oriented in a second direction, and wherein the first direction and the second direction intersect each other such that each first reinforcement bar intersects at least one second reinforcement bar.

19. A method of strengthening a photovoltaic device that includes an encapsulation substrate defining a connection aperture and a transparent substrate, wherein a first lead extends through the connection aperture from a plurality of thin film layers on an inner surface of the transparent substrate that is opposite of a front surface, wherein the plurality of thin film layers define a plurality of photovoltaic cells connected to each other in a circuit, and wherein the first lead is connected to one part of the circuit, the method comprising:
applying a reinforcement element onto the front surface of the transparent substrate and positioned opposite from the connection aperture defined in the encapsulation substrate to support the transparent substrate in an area opposite to the connection aperture defined by the encapsulation substrate.

20. A kit for use with a transparent substrate defining a plurality of photovoltaic cells connected in series to each other on an inner surface and a first lead connected to one of the photovoltaic cells, wherein the transparent substrate defines a front surface opposite to the inner surface; the kit comprising:
an encapsulation substrate defining a connection aperture configured to allow the first lead to pass therethrough upon lamination to the inner surface of the transparent substrate; and,
a reinforcement element configured to be applied onto the front surface of a transparent substrate and positioned opposite from the connection aperture defined in the encapsulation substrate, the reinforcement element being configured to support the transparent substrate in an area opposite to the connection aperture defined by the encapsulation substrate.
